(19) United States
(12) Patent Application Publication
(10) Pub. No.: US 2025/0107038 A1
(43) Pub. Date: Mar. 27, 2025

(54) JET IMPINGEMENT COOLING SYSTEMS AND RELATED METHODS OF COOLING HIGH HEAT FLUX DEVICES

(71) Applicant: Colorado State University Research Foundation, Fort Collins, CO (US)

(72) Inventors: Todd M. Bandhauer, Fort Collins, CO (US); David R. Hobby, Wellington, CO (US); Zachary H. Gilvey, Fort Collins, CO (US)

(73) Assignee: Colorado State University Research Foundation, Fort Collins, CO (US)

(21) Appl. No.: 18/843,243

(22) PCT Filed: Mar. 2, 2023
(86) PCT No.: PCT/US2023/063557

§ 371 Date: Aug. 31, 2024

Related U.S. Application Data
(60) Provisional application No. 63/315,751, filed on Mar. 2, 2022.

(51) Int. Cl. H05K 7/20

(52) U.S. Cl. CPC H05K 7/20272; H05K 7/2039

(57) ABSTRACT

Aspects of the present disclosure include a jet impingement cooling system configured to cool high heat flux devices via a cooling fluid. The jet impingement cooling system may include a heatsink and a first supply surface. The heatsink is coupled to the high heat flux device or capable of being coupled to the high heat flux device. The heatsink includes a first impingement surface having exit orifices and impingement regions. The exit orifices are spaced-apart from each other and defined in the first impingement surface. The impingement regions are located between adjacent exit orifices. The first supply surface is spaced-apart from the first impingement surface and includes injection ports spaced-apart from each other and defined in the supply surface. The injection ports are oriented such that impingement jets therefrom are directed to impinge against the impingement regions.

### CROSS REFERENCE TO RELATED APPLICATION

This application claims priority to, and incorporates by reference herein in its entirety, U.S. Provisional Patent Appln. No. 63/315,751 filed on Mar. 2, 2022.

### FIELD OF THE INVENTION

This application relates to systems and methods for cooling high heat flux devices such as lasers, integrated circuits, power inverters, etc. In particular, this application relates to jet impingement cooling systems and related methods of cooling high heat flux devices.

### BACKGROUND OF THE INVENTION

Jet impingement is a cooling method for high heat flux devices such as lasers, integrated circuits, power inverters and more. Jet impingement cooling has been well recognized in literature for its potential to attain high heat transfer coefficients when compared to conventional methods such as microchannel cooling.

When scaling from a single impingement jet to an array of jets, there have been significant challenges, primarily with jet-to-jet interference, degrading heat transfer performance. In instances where jet-to-jet interference has been addressed to some extent, the associated manufacturing costs are significant. Finally, the heat transfer area per unit volume provided by jet impingement cooling systems known in the art is simply inadequate.

Consequently, there is a need in the art for systems and methods that economically address the jet-to-jet interference issues presented by jet impingement cooling.

### SUMMARY OF THE INVENTION

Reference will now be made in detail to the exemplary embodiments, which are illustrated in the accompanying drawings. Wherever possible, the same reference numbers will be used throughout the drawings to refer to the same or like parts.

In a first exemplary embodiment of the present invention, a jet impingement cooling system is disclosed. The jet impingement cooling system is configured to cool high heat flux devices via a cooling fluid. In some embodiments, the fluid is a gas such as, for example, air, nitrogen, supercritical carbon dioxide, etc. In other embodiments, the fluid is a liquid such as, for example, a non-conducting electronics cooling liquid (e.g., fluorocarbon fluids (Fluorinert), hydrofluoro-ether fluids (HFE), mineral oil, other proprietary cooling fluids (e.g., Submer, etc.)), water, etc. In other embodiments, the fluid is a two-phase fluid such as, for example, refrigerant.

The jet impingement cooling system may include a heatsink body, a first heatsink fin, an exit channel, a first injection wall, and a cooling supply channel. The heatsink body is coupled to the high heat flux device or capable of being coupled to the high heat flux device.

The first heatsink fin extends from a heatsink body and includes an impingement face, an exit face, a fin thickness, and a plurality of exit orifices extending through the fin thickness from the impingement face to the exit face. The exit orifices are spaced-apart from each other across the impingement face to define impingement surfaces of the impingement face between the exit orifices. The exit channel is in fluid communication with the plurality of exit orifices at the exit face.

The first injection wall includes a supply-side face, an injection-side face, a wall thickness between the supply-side face and injection-side face, and a plurality of injection ports extending through a wall thickness from the supply-side face to the injection-side face. The plurality of injection ports is oriented such that impingement jets therefrom are directed to the impingement surfaces. The injection-side face is spaced-apart from the impingement face. The cooling supply channel is in fluid communication with the plurality of injection ports at the supply-side face.

In operation, the cooling fluid flows from the cooling supply channel through the injection ports, out the injection ports to impinge against the impingement surfaces and exits through the exit orifices into the exit channel.

In one version of the jet impingement cooling system, the plurality of injection ports is offset from the plurality of exit orifices such that longitudinal axes of the injection ports are not in alignment with longitudinal axes of the exit orifices.

In one version of the jet impingement cooling system, the plurality of injection ports is offset from the plurality of exit orifices such that no boundary of any injection port overlaps with any boundary of any exit orifice where the plurality of injection ports and plurality of exit orifices are superimposed with each other.

In one version of the jet impingement cooling system, the system further includes a second heatsink fin extending from the heatsink body. The second heatsink fin includes an impingement face, an exit face, a fin thickness, and a plurality of exit orifices extending through the fin thickness from the impingement face to the exit face. The exit orifices are spaced-apart from each other across the impingement face to define impingement surfaces of the impingement face between the exit orifices. The second heatsink fin is spaced-apart from the first heatsink fin to at least in part define the exit channel. The exit channel is in fluid communication with the plurality of exit orifices of the first and second heatsink fins at the respective exit faces thereof. The exit orifices of the first heatsink fin and the second heatsink fin are offset from each other such that cooling fluid passing through the exit orifices of the first heatsink fin and second heatsink fin into the exit channel do not run into each other head-on.

In one version of the jet impingement cooling system, the system further includes a second heatsink fin extending from the heatsink body. The second heatsink fin includes an impingement face, an exit face, a fin thickness, and a plurality of exit orifices extending through the fin thickness from the impingement face to the exit face. The exit orifices are spaced-apart from each other across the impingement face to define impingement surfaces of the impingement face between the exit orifices. The second heatsink fin is spaced-apart from the first heatsink fin to at least in part define the exit channel. The exit channel is in fluid communication with the plurality of exit orifices of the first and second heatsink fins at the respective exit faces thereof. The plurality of exit orifices of the first heatsink fin is offset from the plurality of exit orifices of the second heatsink fin such that longitudinal axes of the exit orifices of the first heatsink fin are not in alignment with longitudinal axes of the exit orifices of the second heatsink fin.

In one version of the jet impingement cooling system, the system further includes a second a heatsink fin extending from the heatsink body. The second heatsink fin includes an impingement face, an exit face, a fin thickness, and a plurality of exit orifices extending through the fin thickness from the impingement face to the exit face. The exit orifices are spaced-apart from each other across the impingement face to define impingement surfaces of the impingement face between the exit orifices. The second heatsink fin is spaced-apart from the first heatsink fin to at least in part define the exit channel. The exit channel is in fluid communication with the plurality of exit orifices of the first and second heatsink fins at the respective exit faces thereof. The plurality of exit orifices of the first heatsink fin are offset from the plurality of exit orifices of the second heatsink fin such that no boundary of any exit orifice of the first heatsink fin overlaps with any boundary of any exit orifice of the second heatsink fin where the plurality of exit orifices of the first heatsink fin and plurality of exit orifices of the second heatsink fin are superimposed with each other.

In a second exemplary embodiment of the present invention, a jet impingement cooling system is disclosed. The jet impingement cooling system is configured to cool high heat flux devices via a cooling fluid. In some embodiments, the fluid is a gas such as, for example, air, nitrogen, supercritical carbon dioxide, etc. In other embodiments, the fluid is a liquid such as, for example, a non-conducting electronics cooling liquid (e.g., fluorocarbon fluids (Fluorinert), hydrofluoro-ether fluids (HFE), mineral oil, other proprietary cooling fluids (e.g., Submer, etc.)), water, etc. In other embodiments, the fluid is a two-phase fluid such as, for example, refrigerant.

The jet impingement cooling system may include a heatsink and a first supply surface. The heatsink is coupled to the high heat flux device or capable of being coupled to the high heat flux device. The heatsink includes a first impingement surface having exit orifices and impingement regions. The exit orifices are spaced-apart from each other and defined in the first impingement surface. The impingement regions are located between adjacent exit orifices.

The first supply surface is spaced-apart from the first impingement surface and includes injection ports spaced-apart from each other and defined in the supply surface. The injection ports are oriented such that impingement jets therefrom are directed to impinge against the impingement regions.

In one version of the jet impingement cooling system, in operation, the cooling fluid flows out of the injection ports as the impingement jets to impinge against the impingement regions and then enters the exit orifices.

In one version of the jet impingement cooling system, longitudinal axes of the injection ports are offset from longitudinal axes of the exit orifices. The longitudinal axes of the injection ports may be generally parallel to the longitudinal axes of the exit orifices.

In one version of the jet impingement cooling system, the injection ports are out of alignment with the exit orifices such that no injection port overlaps with any exit orifice when the injection ports and exit orifices are superimposed with each other.

In one version of the jet impingement cooling system, the system further includes a second supply surface, and the heatsink further includes a second impingement surface and an exit channel.

The second supply surface is spaced-apart from the second impingement surface, which is spaced-apart from the first impingement surface. The exit channel is located between the first and second impingement surfaces. The second supply surface includes injection ports spaced-apart from each other and defined in the second supply surface.

The second impingement surface has exit orifices and impingement regions. The exit orifices are spaced-apart from each other and defined in the second impingement surface. The impingement regions of the second impingement surface are located between adjacent exit orifices of the second impingement surface.

The injection ports of the second supply surface are oriented such that impingement jets therefrom are directed to impinge against the impingement regions of the second impingement surface. The exit orifices of the first and second impingement surfaces are in fluid communication with the exit channel.

In one version of the jet impingement cooling system, the exit orifices of the first and the second impingement surfaces are out of alignment with each other such that cooling fluid flows passing through the exit orifices of the first, and the second impingement surfaces into the exit channel do not run into each other head-on.

In one version of the jet impingement cooling system, the exit orifices of the first and the second impingement surfaces are out of alignment with each other such that longitudinal axes of the exit orifices of the first impingement surface are not in alignment with longitudinal axes of the exit orifices of the second impingement surface.

In one version of the jet impingement cooling system, the longitudinal axes of the exit orifices of the first impingement surface are generally parallel to the longitudinal axes of the exit orifices of the second impingement surface.

In one version of the jet impingement cooling system, the exit orifices of the first and the second impingement surfaces are out of alignment with each other such that no exit orifice of the first impingement surface overlaps with any exit orifice of the second impingement surface where the exit orifices of the first impingement surface and exit orifices of the second impingement surface are superimposed with each other.

In a third exemplary embodiment of the present invention, a method of cooling a high heat flux device is disclosed. The cooling method may include supplying a cooling fluid to injection ports defined in a supply surface. The cooling fluid exits the injection ports as impingement jets that impinge against impingement regions of an impingement surface of a heatsink coupled to the high heat flux device. The cooling fluid then flows to and through the exit orifices.

In this method, the impingement surface is spaced-apart from the supply surface, and the impingement regions are located between adjacent exit orifices defined in the impingement surface.

In one version of the cooling method, the cooling fluid, subsequent to impinging the impingement regions, flows laterally along the impingement surface from the impingement regions to the exit orifices before entering the exit orifices.

In one version of the cooling method, the cooling fluid, subsequent to entering the exit orifices, exits the exit orifices to enter an exit channel in which all the exit orifices terminate. In doing so, the fluid flow from any of the exit orifices does not flow head-on into any fluid flow from any exit orifices defined in another impingement surface and also terminating in the exit channel.

### BRIEF DESCRIPTION OF THE DRAWINGS

The foregoing summary, as well as the following detailed description of preferred embodiments of the invention, will be better understood when read in conjunction with the appended drawings. For purposes of illustrating the invention, there are shown in the drawings embodiments which are presently preferred. It should be understood, however, that the invention is not limited to the precise arrangements and instrumentalities shown. In the drawings:

FIG. 1 is diagrammatic depiction of a cooling system configured to cool a high heat flux device via a cooling fluid routed through a jet impingement assembly.

FIG. 2 is a top perspective view of the jet impingement assembly employed as part of the cooling system of FIG. 1.

FIG. 3 is a cutaway top perspective view of the jet impingement assembly of FIG. 2 with portions of the manifold assembly removed for clarity.

FIG. 4 is an enlarged view of a region of the jet impingement assembly of FIG. 3.

FIG. 5 is an exploded top perspective view of the jet impingement assembly of FIG. 2, wherein the manifold assembly is separated from the heatsink assembly.

FIG. 6 is a top perspective view of the heatsink assembly of FIG. 5

FIG. 7 is a diagrammatic cross-sectional elevation as if taken along section line 7-7 in FIG. 2 with the jet impingement assembly operably coupled to the high heat flux device as shown in FIG. 1.

FIG. 8 is an enlarged view of a region the jet impingement assembly of FIG. 7.

FIG. 9 is a diagrammatic depiction of fluid flow from the injection ports, across the heatsink fins, through the exit orifices and out the hot outlet channel, where the injection ports are offset from the exit orifices.

FIGS. 10A-10D are various examples of a pattern of an injection port array superimposed over a pattern of an exit orifice array.

FIG. 11A is a diagrammatic depiction of fluid flow from the injection ports, across the heatsink fins, through the exit orifices and out the hot outlet channel, where the injection ports are offset from the exit orifices and the exit orifices of adjacent heatsink fins forming a common hot outlet channel are also offset from each other.

FIG. 11B is a pattern of a first exit orifice array of a first heatsink fin of FIG. 11A superimposed over a pattern of a second exit orifice array of a second heatsink fin of FIG. 11A.

FIGS. 12A-12F are example shapes that may be employed for either the injection ports and/or the exit orifices forming either the injection port array and/or the exit orifice array.

FIG. 13 are paired perspective and cross-sectional views of a number of example configurations for the injection ports.

FIG. 14 is a cross-sectional elevation as if taken along a segment of section line 7-7 in FIG. 2 and illustrates an embodiment employing a drop jet configuration for the injection ports.

### DETAILED DESCRIPTION

Reference will now be made in detail to the exemplary embodiments, which are illustrated in the accompanying drawings. Wherever possible, the same reference numbers will be used throughout the drawings to refer to the same or like parts.

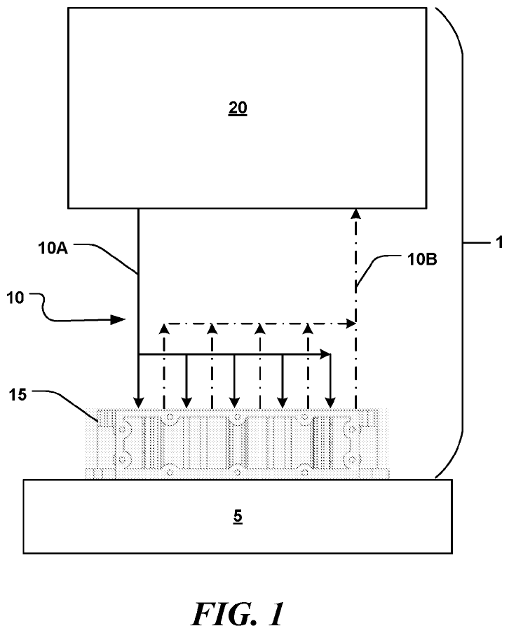

Described herein is a cooling system 1 configured to cool a high heat flux device 5 (e.g., laser, integrated circuit, power inverter, etc.) via a cooling fluid 10, the system 1 being diagrammatically depicted in FIG. 1. In some embodiments, the fluid is a gas such as, for example, air, nitrogen, supercritical carbon dioxide, etc. In other embodiments, the fluid is a liquid such as, for example, a non-conducting electronics cooling liquid (e.g., fluorocarbon fluids (Fluorinert), hydrofluoro-ether fluids (HFE), mineral oil, other proprietary cooling fluids (e.g., Submer, etc.)), water, etc. In other embodiments, the fluid is a two-phase fluid such as, for example, refrigerant.

The system 1 includes a jet impingement assembly 15 in fluid communication with a cooling fluid delivery system 20 (e.g., a fan or blower assembly, compressed air supply, chiller, coolant distribution unit (CDU), vapor compression system, etc.) via a network of supply and return conduits 10A, 10B (e.g, conduits, ductwork, piping, or any other fluid-conveying structure) extending between the cooling delivery system 20 and jet impingement assembly 15. The jet impingement assembly 15 is operably coupled with the high heat flux device 5 in a way to maximize heat transfer from the high heat flux device 5 to the cooling fluid 10 routed through the jet impingement assembly 15.

As will become evident from the following detailed discussion, the jet impingement assembly 15 employs a unique arrangement of injection ports 25, heatsink fins 30 and exit orifices 35 that work together to eliminate the cooling and flow inefficiencies of the jet-to-jet interactions of cooling systems known in the art. Further, the unique arrangement of injection ports 25, heatsink fins 30 and exit orifices 35 results in a jet impingement assembly 15 that is cost-effective to manufacture. Further, this unique arrangement of the jet impingement assembly 15 allows for significantly more heat transfer area per unit volume than jet impingement cooling devices known in the art. In part, this improved cooling capability is facilitated by jetting onto the sides of the heatsink fins 30, rather than being limited to jetting onto a planar surface attached to the high heat flux device.

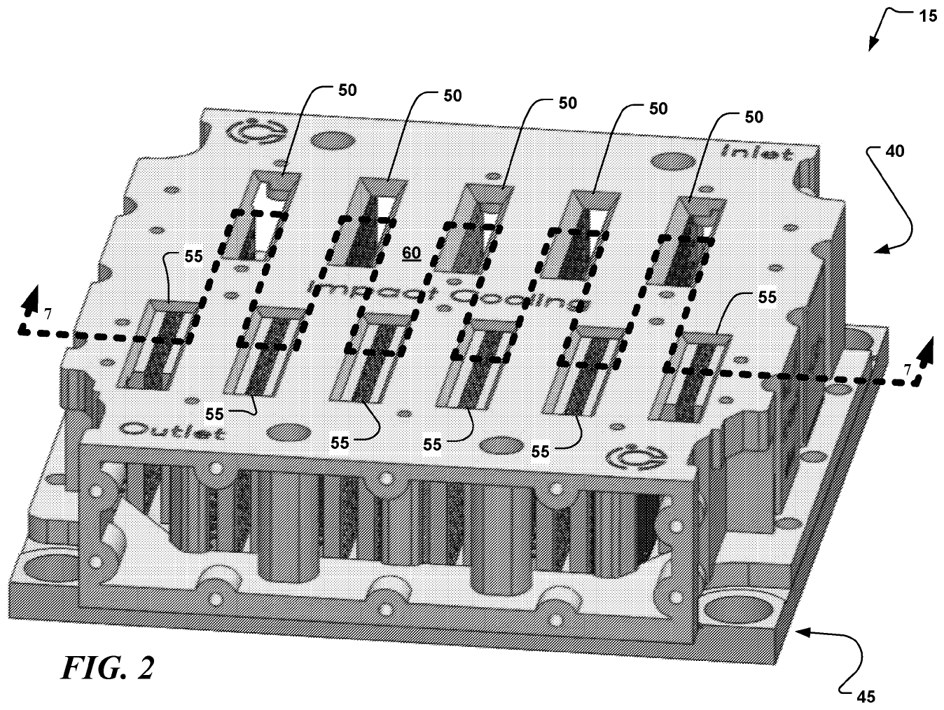

To begin the detailed discussion of the features of the jet impingement assembly 15, reference is made to FIG. 2, which is a top perspective view of the jet impingement assembly 15. As illustrated in FIG. 2, the jet impingement assembly 15 includes a manifold assembly 40 and a heatsink assembly 45. The manifold assembly 40 includes multiple inlets 50 and multiple outlets 55 extending through a top plate 60 of the manifold assembly 40. The inlets 50 and outlets 55 are respectively coupled to the supply and return conduits 10A, 10B extending between the cooling delivery system 20 and jet impingement assembly 15 (see FIG. 1). As described in detail below, the inlets 50 and outlets 55 are, respectively, in fluid communication with the injection ports 25 and exit orifices 35 of the jet impingement assembly 15.

While the inlets 50 and outlets 55 are shown in the figures and discussed herein as being through the top plate 60 of the manifold assembly 40, in other embodiments the inlets and/or outlets can extend through any of the sides of the manifold assembly, or even a combination of sides and top plate of the manifold assembly. Further, the inlets and outlets can be in other configurations, combinations, and numbers than shown in the accompanying figures.

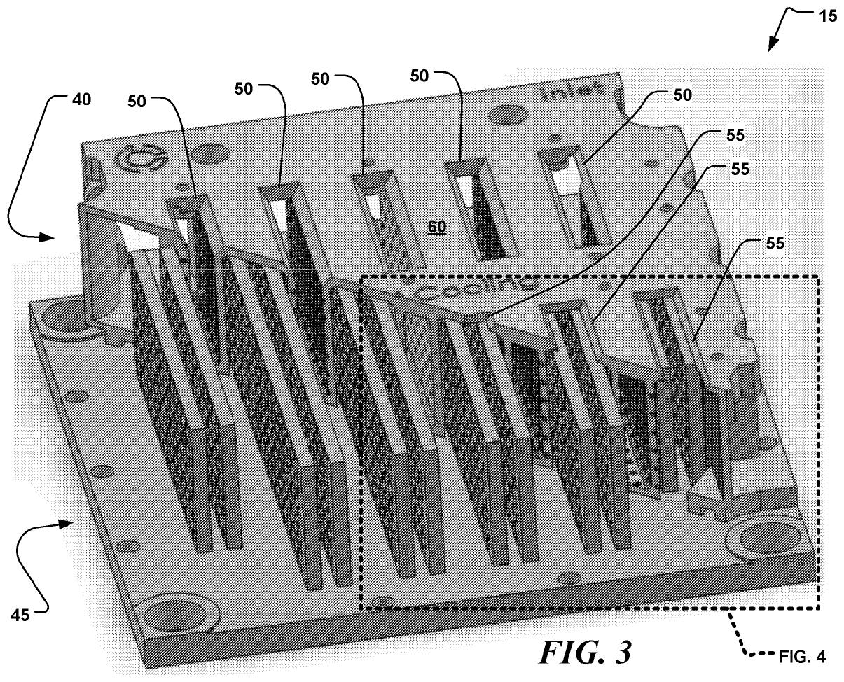

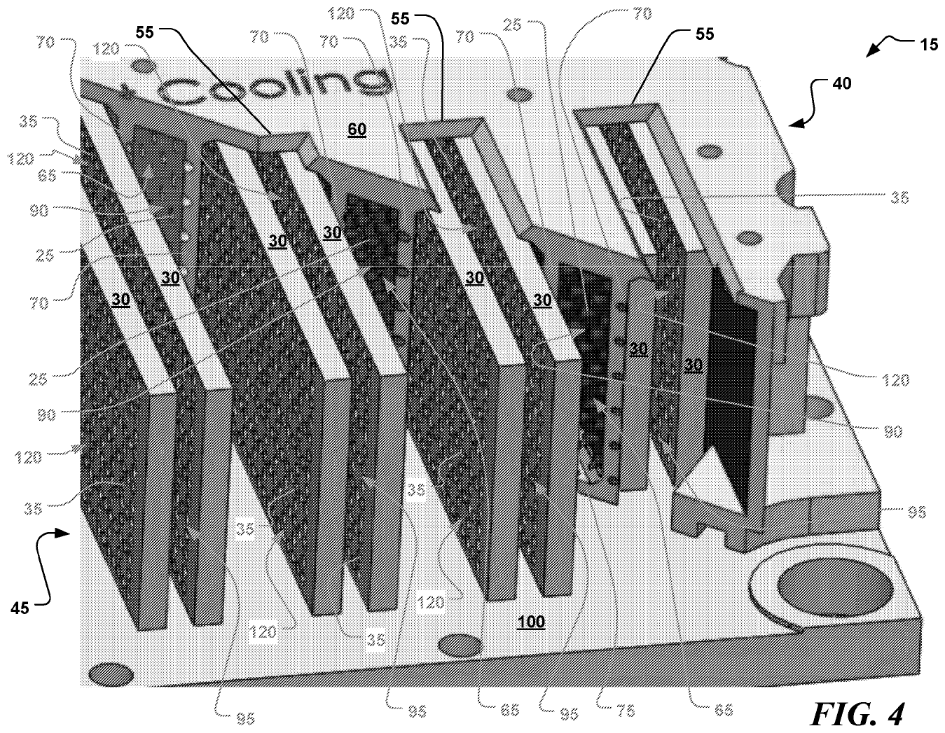

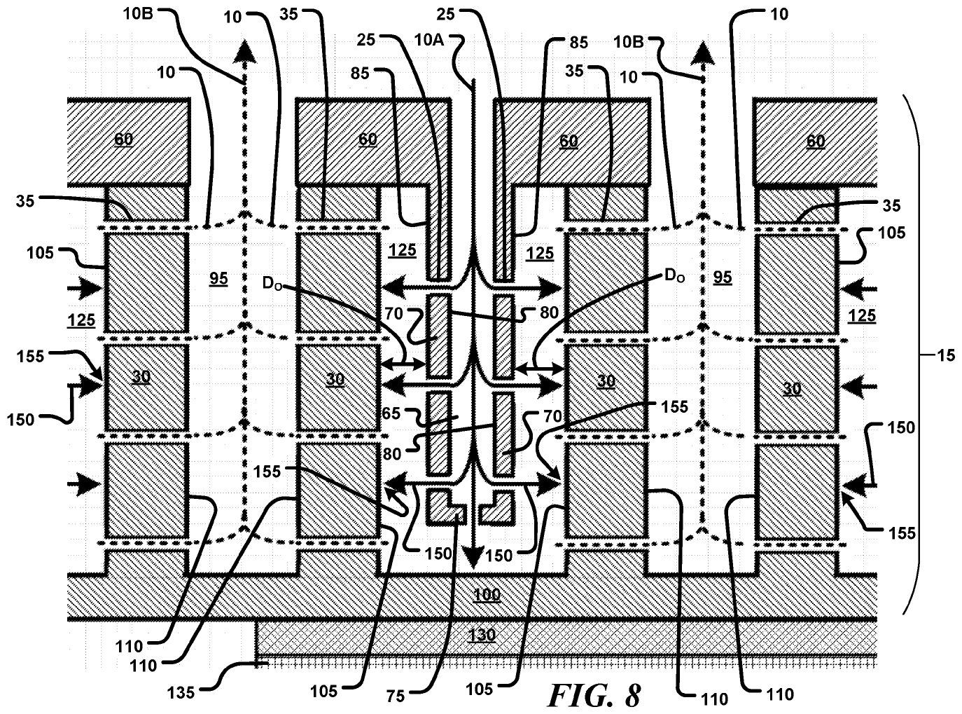

FIG. 3 is a cutaway top perspective view of the jet impingement assembly 15 with portions of the manifold assembly 40 removed for clarity. FIG. 4 is an enlarged view of a region of the jet impingement assembly 15 of FIG. 4. As shown in FIGS. 3 and 4, each inlet 50 extends into the interior of the manifold assembly 40 as a cooling supply channel 65. The cooling supply channels 65 are defined by a pair of spaced-apart cooling sidewalls 70 and a cooling bottom wall 75. Each of these walls 70, 75 includes a channel-side surface 80, a jet-side surface 85 opposite the channel-side surface 80, and many injection ports 25 extending through each wall 70, 75 from the channel-side surface 80 to the jet-side surface 85 to form an injection port array 90 on each surface 80, 85. It should be noted that these surfaces 80, 85 are identifiable in FIGS. 3, 4 and 7 but called out in FIG. 8.

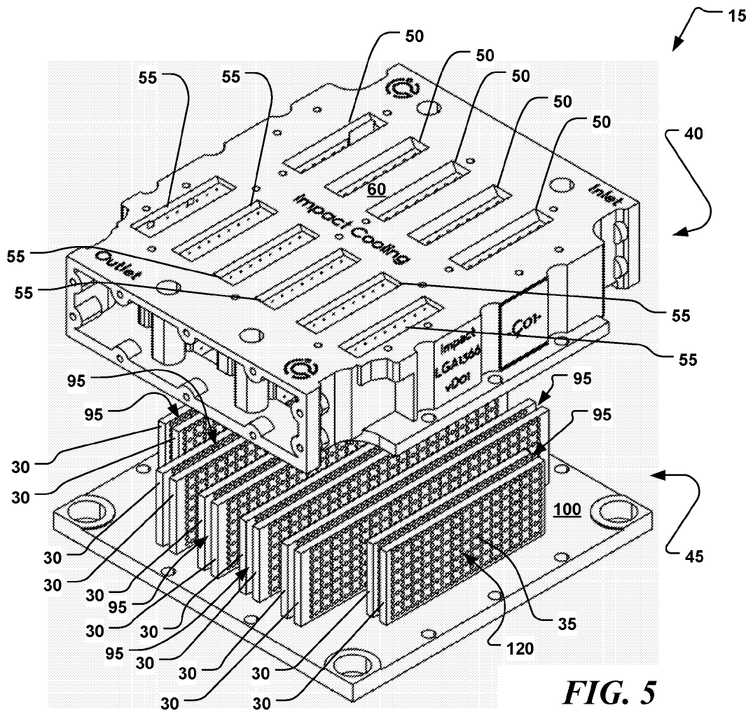

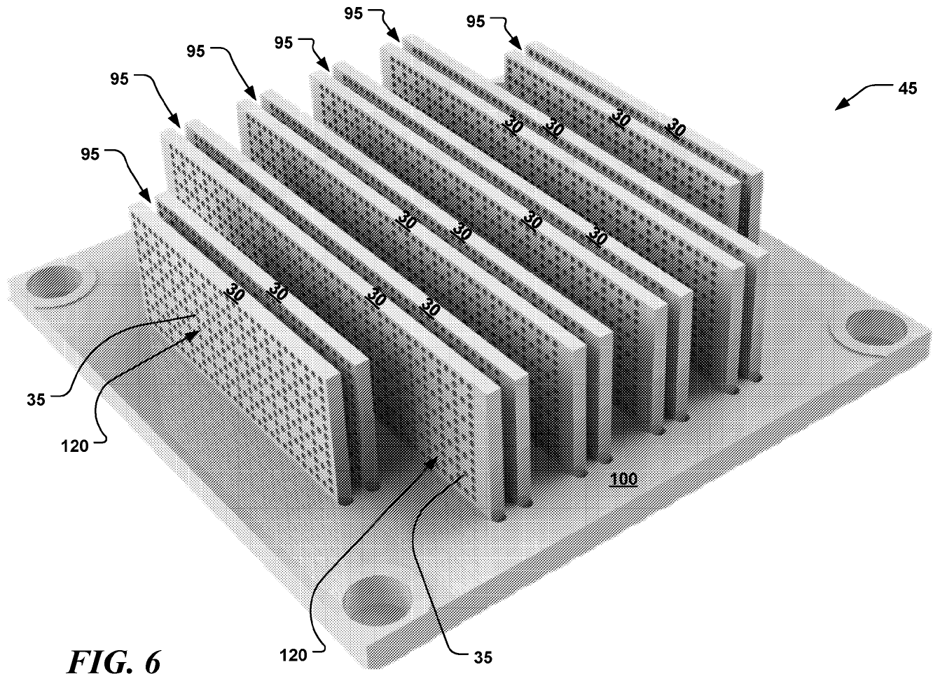

FIG. 5 is an exploded top perspective view of the jet impingement assembly 15 of FIG. 2, wherein the manifold assembly 40 is separated from the heatsink assembly 45. FIG. 6 is a top perspective view of the heatsink assembly 45 by itself. As depicted in FIG. 4-6, each outlet 55 extends from a hot outlet channel 95 located in the interior of the heatsink assembly 45. The hot outlet channels 95 are defined by a pair of spaced-apart heatsink fins 30 vertically extending upward from a heatsink plate 100. Each of the heatsink fins 30 includes an impact-side surface 105, an outlet-side surface 110 opposite the impact-side surface 105, and many exit orifices 35 extending through each heatsink fin 30 from the impact-side surface 105 to the outlet-side surface 110 to form an exit orifice array 120 on each surface 105, 110. It should be noted that these surfaces 105, 110 are identifiable in FIGS. 4-7 but called out in FIG. 8.

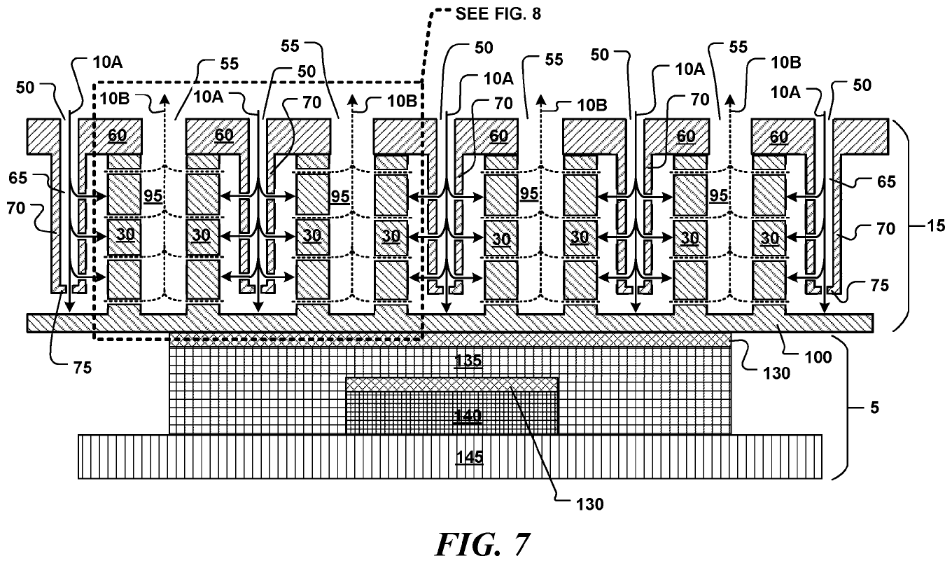

FIG. 7 is a diagrammatic cross-sectional elevation as if taken along section line 7-7 in FIG. 2 with the jet impingement assembly 15 operably coupled to the high heat flux device 5 as shown in FIG. 1. FIG. 8 is an enlarged view of a region of the jet impingement assembly 15 of FIG. 7. As can be understood from FIGS. 3, 4 and 7, the cooling supply channels 65 and pairs of heatsink fins 30 are in an alternating arrangement across the jet impingement assembly 15 with each pair of heatsink fins 30 located between a pair of cooling supply channels 65, or vice versa. Further, as can be understood from FIGS. 6, 7 and 8, each heatsink fin 30 is a planar rectangular body with its planar surfaces 105, 110 parallel to the planar surfaces 105, 110 of the other heatsink fins 30 throughout the heatsink assembly 45.

As can be understood from FIGS. 6, 7 and 8, each cooling sidewall 70 of a cooling supply channel 65 is a planar rectangular body with its planar surfaces 80, 85 parallel to the planar surfaces 80, 85 of the other cooling sidewalls 70 of the cooling supply channels 65 throughout the manifold assembly 40. Further, the planar surfaces 80, 85 of the cooling sidewalls 70 of the cooling supply channels 65 throughout the manifold assembly 40 are parallel to the planar surfaces 105, 110 of the heatsink fins 30 throughout the heatsink assembly 45.

As shown in FIG. 8, each jet-side surface 85 of the cooling sidewalls 70 of the cooling supply channels 65 is spaced-apart from the immediately adjacent impact-side surface 105 of the heatsink fins 30, thereby forming a gap 125 between a cooling side wall 70 and its immediately adjacent heatsink fin 30. Depending on the embodiment, the gap 125 has a distance Do of between approximately 0.05 mm and approximately 5 mm as measured perpendicularly to the adjacent jet-side surface 85 and impact-sidewall surface 105. In one embodiment, the gap 125 has a distance Do of between approximately 0.1 mm and approximately 10 mm as measured perpendicularly to the adjacent jet-side surface 85 and impact-sidewall surface 105. In one embodiment, the gap 125 has a distance Do of between approximately 0.1 mm and approximately 1 mm as measured perpendicularly to the adjacent jet-side surface 85 and impact-sidewall surface 105. In one embodiment, the gap 125 has a distance Do of approximately 0.2 mm as measured perpendicularly to the adjacent jet-side surface 85 and impact-sidewall surface 105.

As noted above with respect to FIG. 1, the jet impingement assembly 15 is operably coupled with the high heat flux device 5 in a way to maximize heat transfer from the high heat flux device 5 to the cooling fluid 10 routed through the jet impingement assembly 15. As illustrated in FIG. 7, this coupling may involve a layer of thermal interface material (TIM) 130 (e.g., thermal grease, hard or soft solder, graphite pad, indium pad, liquid metal, etc.) interposed between the bottom of the heatsink plate 100 and a top of the high heat flux device 5, the top of which may be a heat spreader lid 135. Another layer of TIM 130 may be found between the bottom of the heat spreader lid 135 and a top of an integrated circuit (IC) 140, which may be supported on top of a printed circuit board (PCB) 145, thereby rounding out the components of an example high heat flux device 5.

While the embodiments of the jet impingement assembly 15 discussed above illustrate a heatsink plate 100 interposed between the heatsink fins 30 and the high heat flux device 5, it should be understood the heatsink assembly 45 could simply include the heatsink fins 30 plus any one or more of the elements of the high heat flux device 5 shown in FIG. 7 from which the heatsink fins 30 extends. In one embodiment, the heatsink fins are directly connected to the integrated heat spreader (IHS) 135 of an integrated circuit package.

As can be understood from FIGS. 4, 7 and 8, each cooling sidewall 70 of the cooling supply channels 65 includes an array 90 of injection ports 25. The injection ports 25 generate high velocity fluid impingement jets 150 from the cooling fluid received from the supply conduit 10A extending from the cooling fluid delivery system 20 shown in FIG. 1. The array 90 of injection ports 25 is spaced-apart from the immediately adjacent heatsink fin 30. The heatsink fin 30 includes an array 35 of exit orifices 35 leading to the hot outlet channel 95, which may be coupled to the return conduit 10B leading back to the return side of the cooling fluid delivery system 20 or, alternatively, to an exhaust system, depending on the configuration of the overall cooling fluid delivery system 20.

It should be noted, that while supply and return conduits 10A, 10B are shown in the figures and discussed herein, such conduits are not necessary and in some embodiments the cooling fluid may be supplied to the jet impingement assembly 15 via a cold aisle and/or the cooling fluid exiting the jet impingement assembly 15 may do so by exiting into an exhaust system or simply pass into a hot aisle.

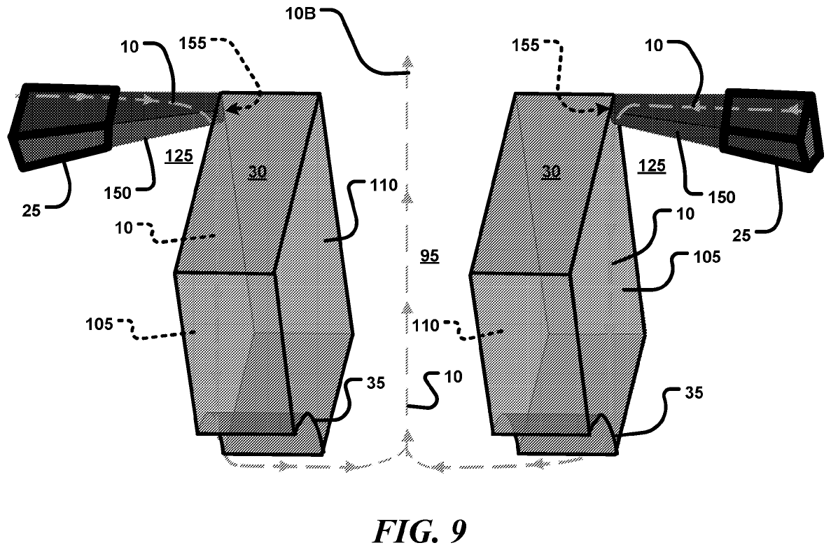

FIG. 9 is a diagrammatic depiction of fluid flow from the injection ports 25, across the heatsink fins 30, through the exit orifices 35 and out the hot outlet channel 95, where the injection ports 25 are offset from the exit orifices 35. As can be understood from FIGS. 8 and 9, because the injection ports 25 are offset relative to the exit orifices 35, the high velocity fluid impingement jets 150 from the injection ports 25 impact the blank target surfaces 155 of the heatsink fin 30 between the exit orifices 35. After impacting the blank target surfaces 155, the cooling fluid 10 flows across the impact-side surfaces 105 of the heatsink fins 30 before exiting through the exit orifices 35 on its way to the return conduit 10B, which provides a pathway back to the cooling fluid delivery system 20 for the cooling fluid 10, as depicted in FIG. 1. In passing along the impact-side surfaces 105 of the heatsink fins 30, the cooling fluid 10 absorbs heat from the heatsink fins 30 via convection and the temperature of the cooling fluid 10 increases.

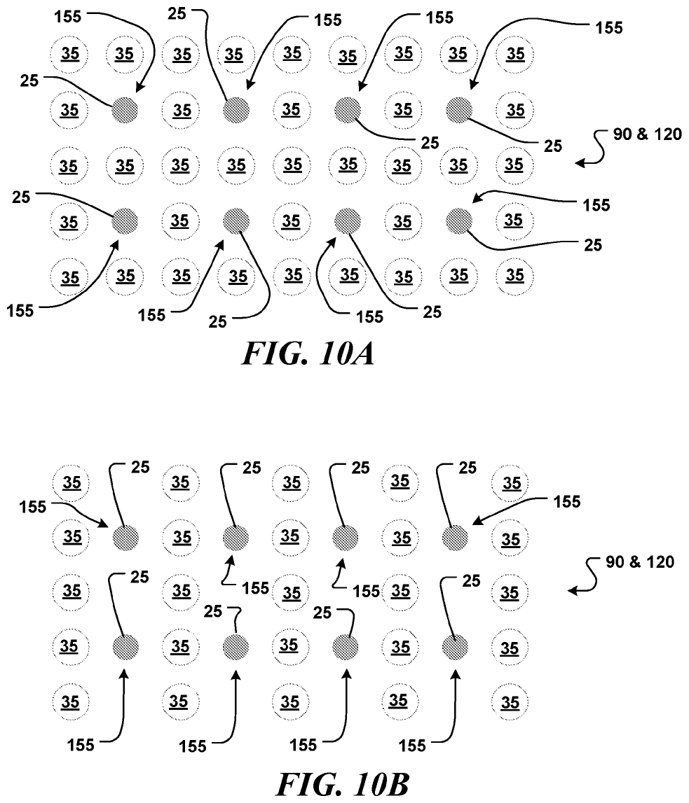

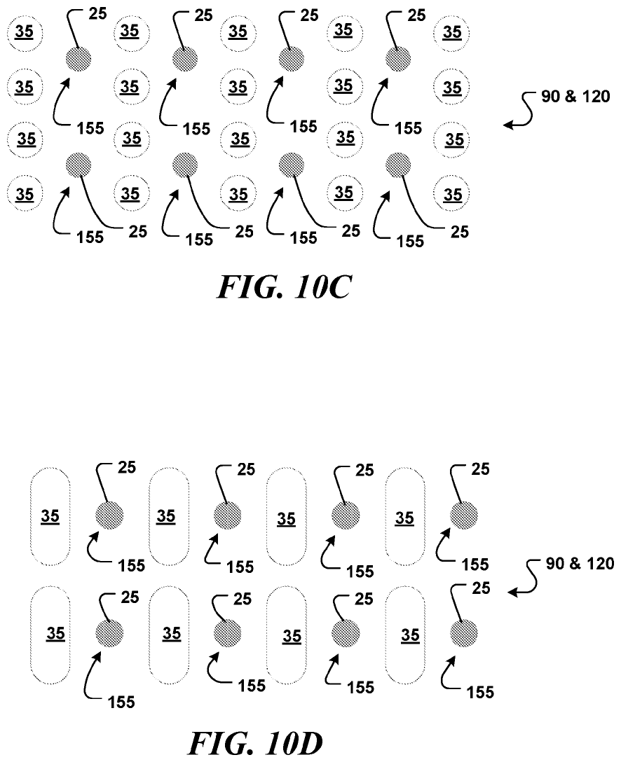

FIGS. 10A-10D are various examples of a pattern of an injection port array 90 superimposed over a pattern of an exit orifice array 120. By superimposing the arrays 90, 120, it can readily be understood that the high velocity fluid impingement jets 150 from the injection ports 25 will impact the blank target surfaces 155 of the heatsink fin 30 between the exit orifices 35.

As can be understood from FIGS. 9-10D, the plurality of injection ports 25 is offset from the plurality of exit orifices 35 such that longitudinal axes of the injection ports 25 are not in alignment with longitudinal axes of the exit orifices 35. Also, it can be seen that the plurality of injection ports 25 is offset from the plurality of exit orifices 35 such that no boundary of any injection port 25 overlaps with any boundary of any exit orifice 35 where the plurality of injection ports 25 and plurality of exit orifices 35 are superimposed with each other.

The offset between the injection port array 90 and the exit orifice array 120 eliminates the cooling and flow inefficiencies of the jet-to-jet interactions of cooling systems known in the art. Further, the benefits from offsetting the arrays 90, 120 allows the jet impingement assembly 15 to maintain junction temperatures lower than that offered by cooling systems known in the art, all while providing a simplified overall design architecture, decreased pressure drop, improved heat transfer, and reduced mass flow rates as compared to those earlier cooling systems.

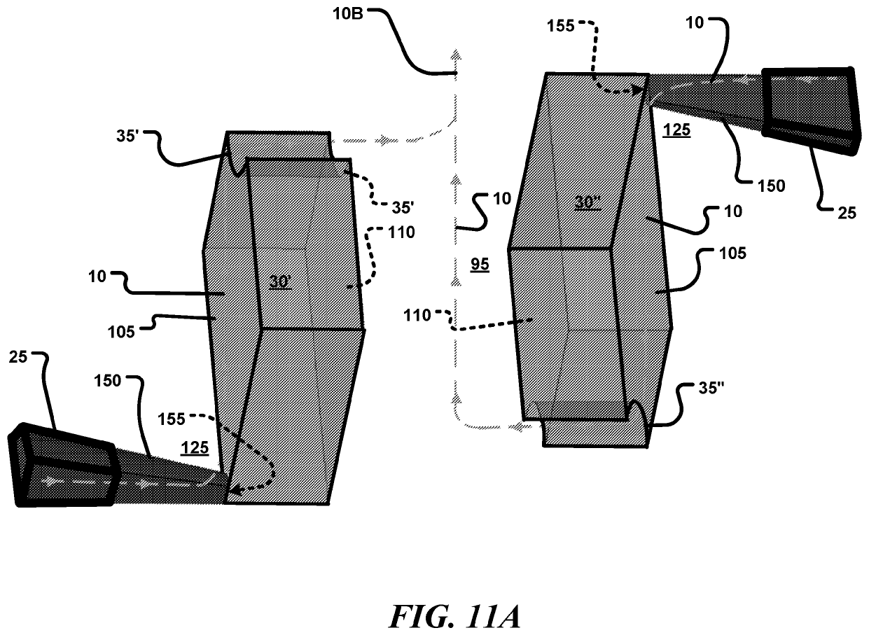

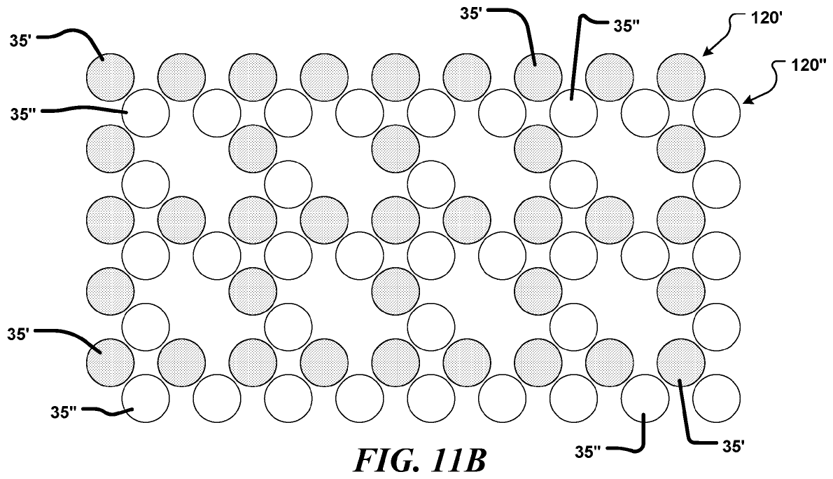

In addition to the injection ports 25 being offset from the exit orifices 35 as discussed above with respect to FIGS. 8-10D, the exit orifices 35 of adjacent heatsink fins 30 can also be offset from each other as now discussed with respect to FIGS. 11A and 11B.

FIG. 11A is a diagrammatic depiction of fluid flow across the heatsink fins 30′, 30″ where the injection ports 25 are offset from the exit orifices 35′, 35″ and the exit orifices 35′, 35″ of adjacent heatsink fins 35′, 35″ forming a common hot outlet channel 95 are also offset from each other. FIG. 11B is a pattern of a first exit orifice array 120′ of a first heatsink fin 30′ of FIG. 11A superimposed over a pattern of a second exit orifice array 120″ of a second heatsink fin 30″ of FIG. 11A.

As can be understood from FIG. 11A, fluid flows from the injection ports 25, across the heatsink fins 30′, 30″, through the exit orifices 35′, 35″ and out the hot outlet channel 95. In doing so, it can be seen that not only are the injection ports 25 offset from the exit orifices 35′, 35″, but the exit orifices 35′, 35″ of adjacent heatsink fins 35′, 35″ forming a common hot outlet channel 95 are also offset from each other.

By superimposing the arrays 120′, 120″ as shown in FIG. 11B, it can readily be understood that the exit orifices 35′, 35″ respectively making up the arrays 120′, 120″ are offset from each other.

As can be understood from FIGS. 11A and 11B, the plurality of exit orifices 35′ of the first heatsink fin 30′ is offset from the plurality of exit orifices 35″ of the second heatsink fin 30″ such that longitudinal axes of the exit orifices 35′ of the first heatsink fin 30′ are not in alignment with longitudinal axes of the exit orifices 35″ of the second heatsink fin 30″.

Also, in one embodiment, the plurality of exit orifices 35′ of the first heatsink fin 30′ is offset from the plurality of exit orifices 35″ of the second heatsink fin 30″ such that no boundary of any exit orifice 35′ of the first heatsink fin 30″ overlaps with any boundary of any exit orifice 35″ of the second heatsink fin 30″ where the plurality of exit orifices 35′ of the first heatsink fin 30′ and plurality of exit orifices 35″ of the second heatsink fin 30″ are superimposed with each other. In other embodiments, the exit orifices 35′, 35″ do overlap when superimposed, but the overlap between the orifices 35′, 35″ is limited to between approximately zero percent to approximately 10 percent, or approximately 10 percent to approximately 30 percent, or approximately 30 percent to approximately 60 percent, or approximately 60 percent to approximately 100 percent of the area of an exit orifice.

Ultimately, the smaller the overlap between the exit orifices 35′, 35″, the smaller the flow inefficiencies because the airflows 10 through the exit orifices 35′, 35″ of the spaced-apart heatsink fins 30′, 30″ run head-on into each other to a lesser extent. Thus, wherein the overlap between the exit orifices is zero percent, the least inefficiency will exist since the airflows through the exit orifices do not run head-on into each other at all, as is the case with the embodiment depicted in FIG. 9.

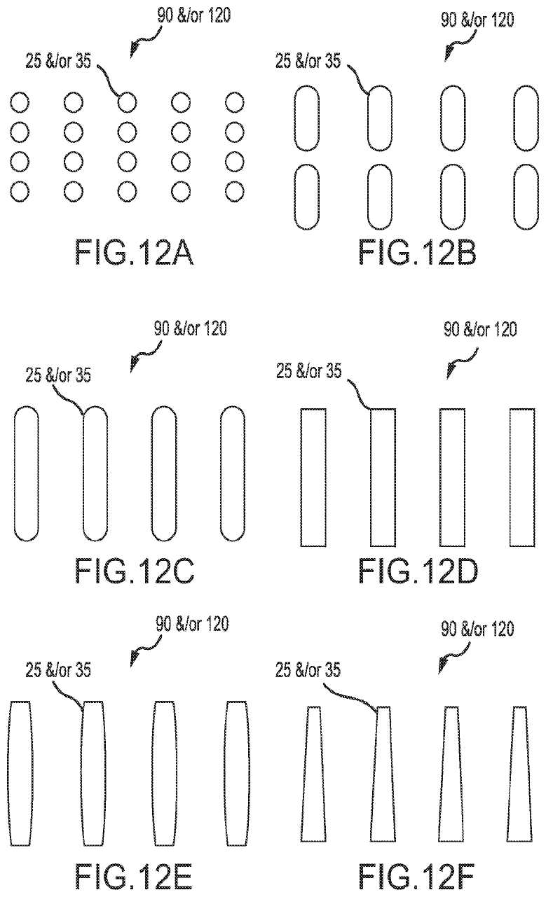

FIGS. 12A-12F are example shapes that may be employed for either the injection ports 25 and/or the exit orifices 35 forming either the injection port array 90 and/or the exit orifice array 120. For example, the injection ports 25 and/or the exit orifices 35 may have circular, oval, elongated oval, rectangular, trapezoidal or any of an unlimited host of possible candidate shapes, including, but not limited to those recited herein and/or shown in FIGS. 12A-12F. The injection port array 90 and/or the exit orifice array 120 may even employ two or more different shapes for its injection ports 25 and/or the exit orifices 35.

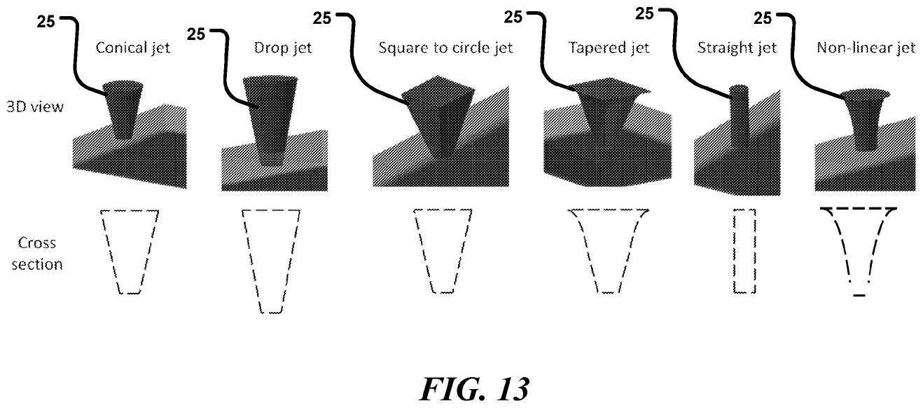

FIG. 13 illustrates that the injection ports 25 may come in a host of configurations. Examples of possible configurations include, but are not limited to, conical jets, drop jets, square to circle jets, tapered jets, straight jets and non-linear jets. These various injection port designs may provide a variety of desirable performance characteristics, may be useful to achieve specific velocity, and may be more suitable to specific manufacturing techniques.

While it is possible that the exit orifices 35 could come in any one or more of the configurations depicted in FIG. 13, a common configuration would be similar to a straight jet, although of much larger diameter, as can be understood from FIGS. 10A-10D.

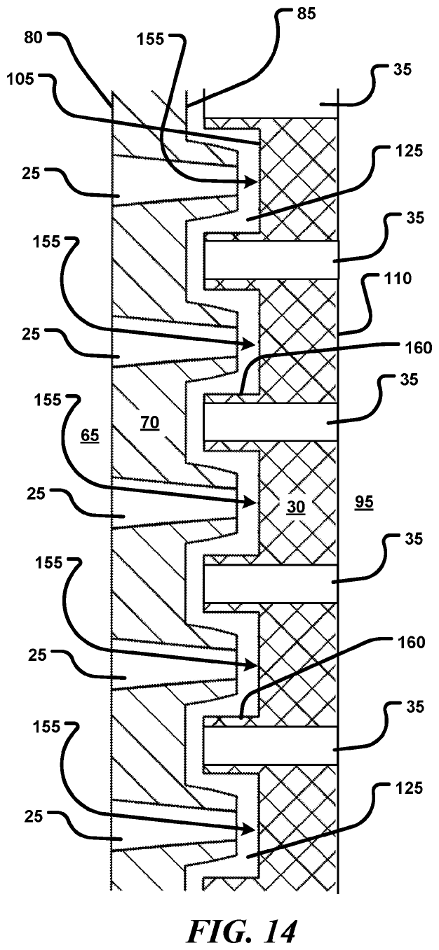

FIG. 14 is a cross-sectional elevation as if taken along a segment of section line 7-7 in FIG. 2 and illustrates an embodiment employing a drop jet configuration for the injection ports 25. As indicated in FIG. 14, the drop jet injection ports 25 extend past the jet-side surface 85 of the cooling sidewall 70 and are oriented such that the high velocity fluid impingement jets 150 impact the blank target surfaces 155. The exit orifices 35 may or may not extend past the impact-side surface 105 of the heatsink fin 30. Regardless, the cooling fluid 10 after impacting the blank target surfaces 155 flows into and through the exit orifices 35 and into the hot outlet channel 95.

Such a configuration as illustrated in FIG. 14 allows for the injection ports 25 to be positioned closer to the blank target surfaces 155 while still allowing for heat transfer enhancement structures 160 to project outwardly from the impact-side surface 105 of the heatsink fin 30. In some instances, some or all of the heat transfer enhancement structures 160 may be combined with the exit orifices 35, as shown in FIG. 14. In other embodiments, the heat transfer enhancement structures 160 may be solid extensions of the heatsink fin 30 and the exit orifices 35 are located elsewhere on the impact-side surface 105 of the heatsink fin 30 spaced-away from the injection ports 25 and the blank target surfaces 155 in a manner similar to that discussed above with respect to FIGS. 10A-10D.

Ultimately, placing the injection ports 25 closer to the blank target surfaces 155 enhances the heat transfer coefficient. The heat transfer enhancement structures 160 (pins, fins or other structures) and the “drop jets” are nested so as to not interfere with one another. This extension of the surface provided by the heat transfer enhancement structures 160 also enhances heat transfer performance.

It should be understood from the foregoing that, while particular aspects have been illustrated and described, various modifications can be made thereto without departing from the spirit and scope of the invention as will be apparent to those skilled in the art. Such changes and modifications are within the scope and teachings of this invention as defined in the claims appended hereto.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” and “approximately” and variations thereof as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

What is claimed is:

1. A jet impingement cooling system configured to cool a high heat flux device via a cooling fluid, the system comprising:
a heatsink body coupled to the high heat flux device or capable of being coupled to the high heat flux device;
a first heatsink fin extending from the heatsink body and including an impingement face, an exit face, a fin thickness, and a plurality of exit orifices extending through the fin thickness from the impingement face to the exit face, the exit orifices being spaced-apart from each other across the impingement face to define impingement surfaces of the impingement face between the exit orifices;
an exit channel in fluid communication with the plurality of exit orifices at the exit face,
a first injection wall including a supply-side face, an injection-side face, a wall thickness between the supply-side face and injection-side face, and a plurality of injection ports extending through a wall thickness from the supply-side face to the injection-side face, the plurality of injection ports being oriented such that impingement jets therefrom are directed to the impingement surfaces, the injection-side face being spaced-apart from the impingement face;
a cooling supply channel in fluid communication with the plurality of injection ports at the supply-side face,
wherein, in operation, the cooling fluid flows from the cooling supply channel through the injection ports, out the injection ports to impinge against the impingement surfaces and exit through the exit orifices into the exit channel.

2. The jet impingement cooling system of claim 1, wherein the plurality of injection ports is offset from the plurality of exit orifices such that longitudinal axes of the injection ports are not in alignment with longitudinal axes of the exit orifices.

3. The jet impingement cooling system of claim 1, wherein the plurality of injection ports is offset from the plurality of exit orifices such that no boundary of any injection port overlaps with any boundary of any exit orifice where the plurality of injection ports and plurality of exit orifices are superimposed with each other.

4. The jet impingement cooling system of claim 1, further comprising a second heatsink fin extending from the heatsink body and including an impingement face, an exit face, a fin thickness, and a plurality of exit orifices extending through the fin thickness from the impingement face to the exit face, the exit orifices being spaced-apart from each other across the impingement face to define impingement surfaces of the impingement face between the exit orifices, the second heatsink fin being spaced-apart from the first heatsink fin to at least in part define the exit channel, the exit channel being in fluid communication with the plurality of exit orifices of the first and second heatsink fins at the respective exit faces thereof.

5. The jet impingement cooling system of claim 4, wherein the exit orifices of the first heatsink fin and the second heatsink fin are offset from each other such that cooling fluid passing through the exit orifices of the first heatsink fin and second heatsink fin into the exit channel do not run into each other head-on.

6. The jet impingement cooling system of claim 4, wherein the plurality of exit orifices of the first heatsink fin is offset from the plurality of exit orifices of the second heatsink fin such that longitudinal axes of the exit orifices of the first heatsink fin are not in alignment with longitudinal axes of the exit orifices of the second heatsink fin.

7. The jet impingement cooling system of claim 4, wherein the plurality of exit orifices of the first heatsink fin is offset from the plurality of exit orifices of the second heatsink fin such that no boundary of any exit orifice of the first heatsink fin overlaps with any boundary of any exit orifice of the second heatsink fin where the plurality of exit orifices of the first heatsink fin and plurality of exit orifices of the second heatsink fin are superimposed with each other.

8. A jet impingement cooling system configured to cool a high heat flux device via a cooling fluid, the system comprising:
a heatsink coupled to the high heat flux device or capable of being coupled to the high heat flux device, the heatsink including a first impingement surface having exit orifices and impingement regions, the exit orifices spaced-apart from each other and defined in the first impingement surface, and the impingement regions located between adjacent exit orifices; and
a first supply surface spaced-apart from the first impingement surface and including injection ports spaced-apart from each other and defined in the supply surface, the injection ports oriented such that impingement jets therefrom are directed to impinge against the impingement regions.

9. The jet impingement cooling system of claim 8, wherein, in operation, the cooling fluid flows out of the injection ports as the impingement jets to impinge against the impingement regions and then enters the exit orifices.

10. The jet impingement cooling system of claim 8, wherein longitudinal axes of the injection ports are offset from longitudinal axes of the exit orifices.

11. The jet impingement cooling system of claim 10, wherein longitudinal axes of the injection ports are generally parallel to the longitudinal axes of the exit orifices.

12. The jet impingement cooling system of claim 8, wherein the injection ports are out of alignment with the exit orifices such that no injection port overlaps with any exit orifice when the injection ports and exit orifices are superimposed with each other.

13. The jet impingement cooling system of claim 8, further comprising a second supply surface and wherein the heatsink further includes a second impingement surface and an exit channel, the second supply surface spaced-apart from the second impingement surface, which is spaced-apart from the first impingement surface, the exit channel located between the first and second impingement surfaces, the second supply surface including injection ports spaced-apart from each other and defined in the second supply surface, the second impingement surface having exit orifices and impingement regions, the exit orifices spaced-apart from each other and defined in the second impingement surface, the impingement regions of the second impingement surface located between adjacent exit orifices of the second impingement surface, the injection ports of the second supply surface oriented such that impingement jets therefrom are directed to impinge against the impingement regions of the second impingement surface, the exit orifices of the first and second impingement surfaces being in fluid communication with the exit channel.

14. The jet impingement cooling system of claim 13, wherein the exit orifices of the first and the second impingement surfaces are out of alignment with each other such that cooling fluid flows passing through the exit orifices of the first and the second impingement surfaces into the exit channel do not run into each other head-on.

15. The jet impingement cooling system of claim 13, wherein the exit orifices of the first and the second impingement surfaces are out of alignment with each other such that longitudinal axes of the exit orifices of the first impingement surface are not in alignment with longitudinal axes of the exit orifices of the second impingement surface.

16. The jet impingement cooling system of claim 15, wherein the longitudinal axes of the exit orifices of the first impingement surface are generally parallel to the longitudinal axes of the exit orifices of the second impingement surface.

17. The jet impingement cooling system of claim 13, wherein the exit orifices of the first and the second impingement surfaces are out of alignment with each other such that no exit orifice of the first impingement surface overlaps with any exit orifice of the second impingement surface where the exit orifices of the first impingement surface and exit orifices of the second impingement surface are superimposed with each other.

18. A method of cooling a high heat flux device, the method comprising:
supplying a cooling fluid to injection ports defined in a supply surface,
the cooling fluid exiting the injection ports as impingement jets that impinge against impingement regions of an impingement surface of a heatsink coupled to the high heat flux device, the impingement surface being spaced-apart from the supply surface, the impingement regions being located between adjacent exit orifices defined in the impingement surface,
the cooling fluid then flowing to and through the exit orifices.

19. The method of claim 18, wherein the cooling fluid, subsequent to impinging the impingement regions, flows laterally along impingement surface from the impingement regions to the exit orifices before entering the exit orifices.

20. The method of claim 18, wherein the cooling fluid, subsequent to entering the exit orifices, exits the exit orifices to enter an exit channel in which all the exit orifices terminate, and a fluid flow from any of the exit orifices does not flow head-on into any fluid flow from any exit orifices defined in another impingement surface and also terminating in the exit channel.
